(19) United States
(12) Patent Application Publication
(10) Pub. No.: US 2015/0001509 A1
(43) Pub. Date: Jan. 1, 2015

(54) COMPOSITION

(71) Applicants: Cambridge Display Technology Limted, Godmanchester (GB); Sumitomo Chemical Company Limited, Tokyo (JP)

(72) Inventors: Annette Steudel, Cambridge (GB); Kiran Kamtekar, Godmanchester (GB); Martin Humphries, Godmanchester (GB)

(21) Appl. No.: 14/317,921

(22) Filed: Jun. 27, 2014

(30) Foreign Application Priority Data
Jun. 27, 2013 (GB) 1311517.5

(51) Int. Cl. H01L 51/00; H01L 51/56; H01L 51/50

(52) U.S. Cl. CPC H01L 51/0035; H01L 51/5004; H01L 51/56; H01L 51/0085
USPC 257/40; 438/46; 252/519.21

(57) ABSTRACT

An OLED formed on a glass or plastic substrate includes an anode, a cathode, and at least one light emitting layer between the anode and cathode. Additional layers may include hole transporting, electron transporting, hole blocking and electron blocking layers.

### RELATED APPLICATIONS

This application claims foreign priority benefits under 35 U.S.C. §119(a)-(d) or 35 U.S.C. §365(b) of British application number 1311517.5, filed Jun. 27, 2013, the entirety of which is herein incorporated by reference.

### BACKGROUND

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED device may comprise a substrate carrying an anode, a cathode and one or more organic light-emitting layers between the anode and cathode.

Holes are injected into the OLED device through the anode and electrons are injected through the cathode during operation of the device. Holes in the highest occupied molecular orbital (HOMO) and electrons in the lowest unoccupied molecular orbital (LUMO) of a light-emitting material present within the OLED device combine to form an exciton that releases its energy as light.

Within an OLED device, the light-emitting material may be used as a dopant within a light emitting layer. The light-emitting layer may comprise a semiconducting host material and the light-emitting dopant, and energy will be transferred from the host material to the light-emitting dopant. For example, J. Appl. Phys. 65, 3610, 1989 discloses a host material doped with a fluorescent light-emitting dopant (that is, a light-emitting material in which light is emitted via decay of singlet excitons).

Exemplary light-emitting materials include small molecule, polymeric and dendrimeric materials. Suitable light-emitting polymers include poly(arylene vinylenes) such as poly(p-phenylene vinylenes) and polyarylenes such as polyfluorenes.

As well as fluorescent light-emitting dopants, phosphorescent dopants used with a suitable host material are also known.

Known phosphorescent dopants include complexes of heavy transition metals.

WO 2008/090795 discloses compounds of formula (I):

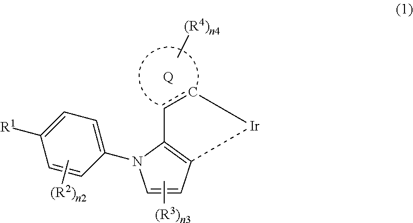

wherein R1 represents a group; R2-R4 independently represent a substituent; n2 represents a number of 0-4; n4 represents a number of 0-8; and Q represents an atomic group necessary for forming an aromatic hydrocarbon ring or an aromatic heterocyclic ring.

U.S. Pat. No. 7,659,010 describes a blue light-emitting transition metal containing compound having the following formula:

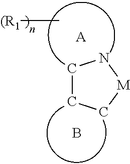

wherein A can be triazole or tetrazole, B is a five- or six-membered aryl or heteroaryl ring and M is a d-block transition metal.

JP2009-001742 discloses compounds of formula (I):

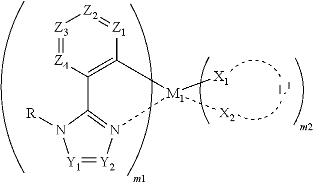

wherein M is selected from certain transition metal elements; Z₁—Z₄ are each N or substituted C, and at least one Z₁—Z₄ is N; Y₁ and Y₂ are each N or substituted C; R is alkyl, aryl or heteroaryl; m₁ is 1-3; m₂ is 0-2 wherein m₁+m₂ is 2 or 3; and X₁-L₁-X₂ is certain bidentate ligands.

A wide range of host materials are known. Examples of small molecule hosts include 4,4′-bis(carbazol-9-yl)biphenyl), known as CBP, and (4,4′,4′-tris(carbazol-9-yl)triphenylamine), known as TCTA, disclosed in Ikai et al., Appi. Phys. Lett., 79 no. 2, 2001, 156; and triarylamines such as tris-4-(N-3-methylphenyl-N-phenyl)phenylamine, known as MTDATA. Polymeric hosts include poly(vinyl carbazole) disclosed in, for example, Appl. Phys. Lett. 2000, 77(15), 2280; polyfluorenes in Synth. Met. 2001, 116, 379, Phys. Rev. B 2001, 63, 235206 and Appl. Phys. Lett. 2003, 82(7), 1006; and poly(para-phenylenes) in J. Mater. Chem. 2003, 13, 50-55.

WO 2008/025997 discloses small molecule and polymeric hosts containing triazine.

As will be understood by the skilled person, the lowest excited triplet energy level of a host material is preferably at least the same as or higher than that of the phosphorescent material or materials that it is used with. A particular challenge is the development of host materials for phosphorescent blue materials due to the high triplet energy level of these materials.

It is an object of the invention to provide a high efficiency phosphorescent emitter—host composition, including a high efficiency blue phosphorescent emitter—host composition.

### SUMMARY OF THE INVENTION

In a first aspect, the invention provides a composition comprising a compound of formula (I) and a host material:

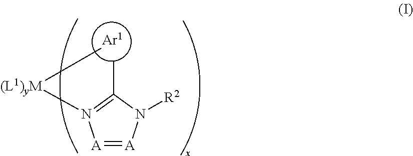

wherein:
Ar¹ is a nitrogen-containing heteroaryl group that may be unsubstituted or substituted with one or more substituents;
R² is a substituent;
A is independently in each occurrence N or CR³ wherein R³ is H or a substituent;
M is a transition metal or metal ion;
x is a positive integer of at least 1;
y is 0 or a positive integer; and
each L¹ is independently a mono- or polydentate ligand different from ligands of formula

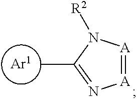

and wherein the host has a LUMO level of at least 2.0 eV from vacuum level.

In a second aspect the invention provides a formulation comprising a composition according to the first aspect and at least one solvent.

In a third aspect the invention provides an organic light-emitting device comprising an anode, a cathode and a light-emitting layer between the anode and the cathode, the light-emitting layer comprising a composition according to the first aspect.

In a fourth aspect the invention provides a method of forming an organic light-emitting device according to the third aspect, the method comprising the steps of forming the light-emitting layer over one of the anode and cathode, and forming the other of the anode and cathode over the light-emitting layer.

“Aryl” and “heteroaryl” as used herein includes monocyclic and polycyclic aromatic and heteroaromatic groups unless specifically stated otherwise.

### DESCRIPTION OF THE DRAWINGS

The invention will now be described in more detail with reference to the Figures, in which:

FIG. 1 illustrates schematically an OLED according to an embodiment of the invention;

FIG. 2 illustrates the energy levels of a device containing a composition according to an embodiment of the invention and energy levels of materials of comparative compositions;

FIG. 3 illustrates photoluminescence spectra for two comparative compositions; and

FIG. 4 illustrates photoluminescence spectra for a composition according to an embodiment of the invention and a comparative composition.

### DETAILED DESCRIPTION OF THE INVENTION

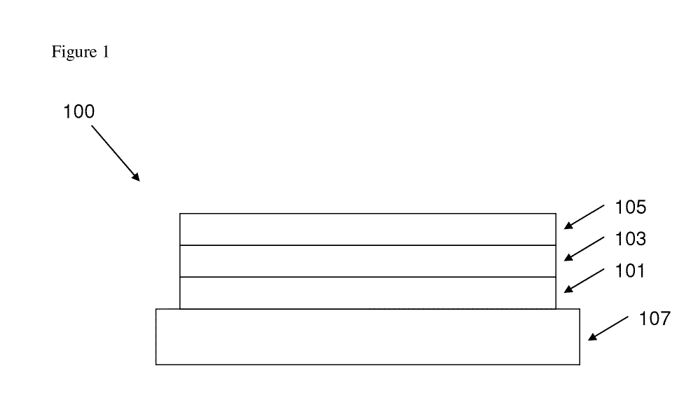

FIG. 1, which is not drawn to any scale, illustrates an OLED 100 according to an embodiment of the invention comprising an anode 101, a cathode 105 and a light-emitting layer 103 between the anode and cathode. The device 100 is supported on a substrate 107, for example a glass or plastic substrate.

One or more further layers may be provided between the anode 101 and cathode 105, for example hole-transporting layers, electron transporting layers, hole blocking layers and electron blocking layers. The device may contain more than one light-emitting layer.

Preferred device structures include:

Anode/Hole-injection layer/Light-emitting layer/Cathode

Anode/Hole transporting layer/Light-emitting layer/Cathode

Anode/Hole-injection layer/Hole-transporting layer/Light-emitting layer/Cathode

Anode/Hole-injection layer/Hole-transporting layer/Light-emitting layer/Electron-transporting layer/Cathode.

Preferably, at least one of a hole-transporting layer and hole injection layer is present. Preferably, both a hole injection layer and hole-transporting layer are present.

A composition of the invention is provided in the light-emitting layer 103. The light-emitting layer 103 may consist essentially of the composition of the invention or may contain one or more further materials, for example one or more charge-transporting materials or one or more further light-emitting materials. For example, the light-emitting layer may contain a blue-emitting compound of formula (I) and one or more further light-emitting compounds, for example one or both of green and red light-emitting compounds.

A blue emitting material may have a photoluminescent spectrum with a peak in the range of no more than 490 nm, optionally in the range of 420-480 nm.

A green emitting material may have a photoluminescent spectrum with a peak in the range of more than 490 nm up to 580 nm, optionally more than 490 nm up to 540 nm.

A red emitting material may optionally have a peak in its photoluminescent spectrum of more than 580 nm up to 630 nm, optionally 585-625 nm.

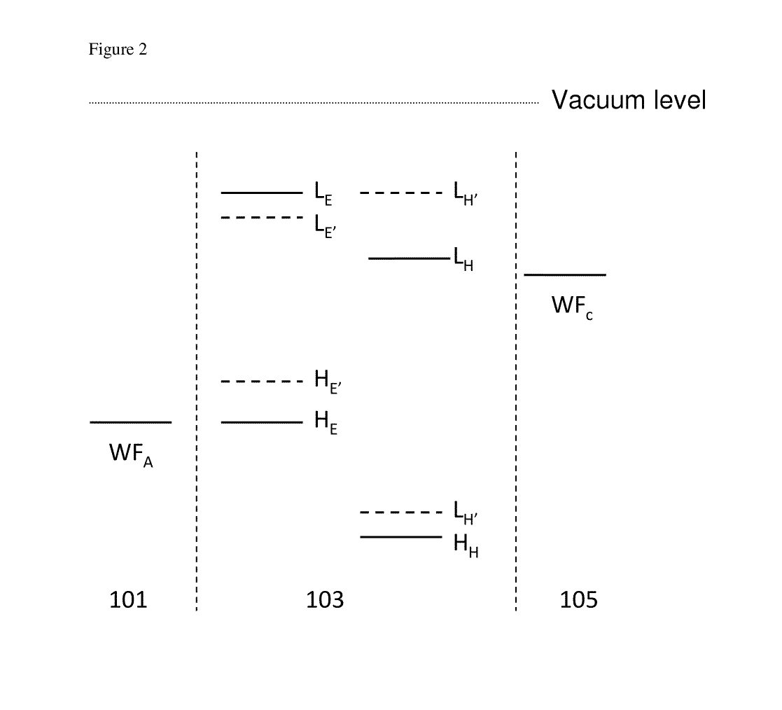

FIG. 2, which is not drawn to any scale, illustrates energy levels of a device having a structure as shown in FIG. 1, wherein WF_{A} is the work function of anode 101; WF_{c} is the work function of cathode 105; H_{E} and L_{E} are, respectively, the HOMO and LUMO levels of a phosphorescent compound of formula (I); H_{H} and L_{H} are, respectively, the HOMO and LUMO levels of an electron-transporting host material; H_{E′} and L_{E′} are, respectively, the HOMO and LUMO levels of a comparative phosphorescent compound wherein Ar¹ of formula (I) is an aromatic group rather than an N-containing heteroaromatic group; and H_{H′} and L_{H′} are, respectively, the HOMO and LUMO levels of a comparative host material.

The HOMO level H_{E} of the compound of formula (I) of this embodiment is significantly deeper (further from vacuum) than HOMO level H_{E′} of the comparative phosphorescent emitter, which may provide efficient hole transport from anode 101 into light-emitting layer 103.

The anode may have a workfunction WF_{A} in the range of about 4.8-5.4 eV.

The compound of formula (I) may have a HOMO level of −4.85 eV or deeper, optionally 4.9 eV or deeper, and optionally in the range of −4.85 to −5.5 eV

Optionally, the gap between the anode workfunction WF_{A} and HOMO level H_{E} of the compound of formula (I) is no more than 0.4 eV, more preferred no more than 0.2 eV.

If a hole-transporting layer is provided between the anode and the light-emitting layer 105 then the gap between HOMO level H_{E} of the compound of formula (I) and a HOMO level of a hole-transporting material of the hole-transporting layer is optionally no more than 0.4 eV, more preferred no more than 0.2 eV.

The LUMO level L_{H} of the host material of this embodiment is significantly deeper than HOMO level L_{H′} of the comparative host material. The host material may provide efficient electron transport from cathode 105 into light-emitting layer 103.

The cathode may have a workfunction WF_{c} in the range of about 2-3 eV.

Anode and cathode work functions can be measured by cyclic voltametry. If the cathode layer nearest the light-emitting layer is a metal then the cathode work function value as measured by cyclic voltammetry can be estimated based on the workfunction of that metal (CRC Handbook of Chemistry and Physics version 2008, p. 12-114).

The host may have a LUMO level of −2.0 eV, −2.1 eV, −2.2 eV or deeper, optionally in the range of −2.3 to −2.75 eV.

The LUMO level L_{H} of the host material may be deeper than LUMO level L_{E} of the compound of formula (I), and may be at least 0.05 eV, 0.1 eV or 0.2 eV deeper than L_{H}.

The composition of the invention may provide good hole and/or electron transport whilst maintaining an emitter HOMO-host LUMO band gap that is large enough to avoid significant excimer formation.

### Phosphorescent Compound

The phosphorescent compound of formula (I) is preferably a blue light-emitting material.

Ar¹ of the compound of formula (I) is a N-containing heteroaromatic group, preferably a monocyclic heteroaromatic group. Preferably, Ar¹ is electron deficient as compared to phenyl. Exemplary electron deficient heteroaromatic groups Ar¹ include 6-membered rings containing one, two or three N atoms, for example pyridine or pyrimidine.

HOMO and LUMO levels as described anywhere herein may be measured by cyclic voltammetry (CV) wherein the working electrode potential is ramped linearly versus time.

When cyclic voltammetry reaches a set potential the working electrode's potential ramp is inverted. This inversion can happen multiple times during a single experiment. The current at the working electrode is plotted versus the applied voltage to give the cyclic voltammogram trace.

Apparatus to measure HOMO or LUMO energy levels by CV may comprise a cell containing a tert-butyl ammonium perchlorate/or tertbutyl ammonium hexafluorophosphate solution in acetonitrile, a glassy carbon working electrode where the sample is coated as a film, a platinum counter electrode (donor or acceptor of electrons) and a reference glass electrode no leak Ag/AgCl. Ferrocene is added in the cell at the end of the experiment for calculation purposes.

### Measurement of the Difference of Potential Between Ag/AgCl/Ferrocene and Sample/Ferrocene.

### Method and Settings:

3 mm diameter glassy carbon working electrode

Ag/AgCl/no leak reference electrode

Pt wire auxiliary electrode

0.1M tetrabutylammonium hexafluorophosphate in acetonitrile

LUMO=4.8-ferrocene (peak to peak maximum average)+onset

Sample: 1 drop of 5 mg/mL in toluene spun at 3000 rpm LUMO (reduction) measurement: A good reversible reduction event is typically observed for thick films measured at 200 mV/s and a switching potential of −2.5V. The reduction events should be measured and compared over 10 cycles, usually measurements are taken on the 3^{rd} cycle. The onset is taken at the intersection of lines of best fit at the steepest part of the reduction event and the baseline.

Optionally, the compound of formula (I) has formula (Ia):

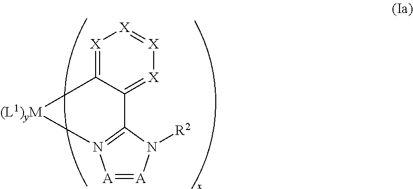

wherein L¹, y, R¹, R² and A are as described above, and X in each occurrence is N or CR³, with the proviso that at least one X is N, and R³ in each occurrence is independently H or a substituent.

Compounds of formula (Ia) may have one of the following formulae:

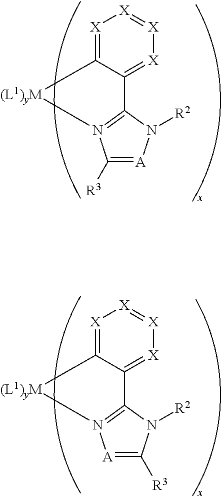

Exemplary substituents R³ may be selected from:
optionally substituted alkyl, optionally C₁₋₂₀ alkyl, wherein one or more non-adjacent C atoms of the alkyl may be replaced with optionally substituted aryl or heteroaryl, O, S, NR⁵, C═O or —COO— wherein R⁵ is H or a substituent, optionally C₁₋₂₀ hydrocarbyl, and one or more H atoms of the alkyl may be replaced with F; and
(Ar⁹), wherein Ar⁹ is independently in each occurrence an aryl or heteroaryl group, optionally phenyl, that may be unsubstituted or substituted with one or more substituents, and w is at least 1, optionally 1, 2 or 3

Substitutents for groups Ar⁹ may be selected from F; CN; NO₂; and C₁₋₂₀ alkyl wherein one or more non-adjacent carbon atoms may be replaced with O, S, NR⁵, C═O or —COO—, and one or more H atoms may be replaced with F, wherein R⁵ is substituent, optionally a C₁₋₄₀ hydrocarbyl group, optionally a group selected from C₁₋₂₀ alkyl and phenyl that may be unsubstituted or substituted with one or more C₁₋₂₀ alkyl groups

Exemplary groups (Ar⁹)_{w} include the following, each of which may be unsubstituted or substituted with one or more substituents:

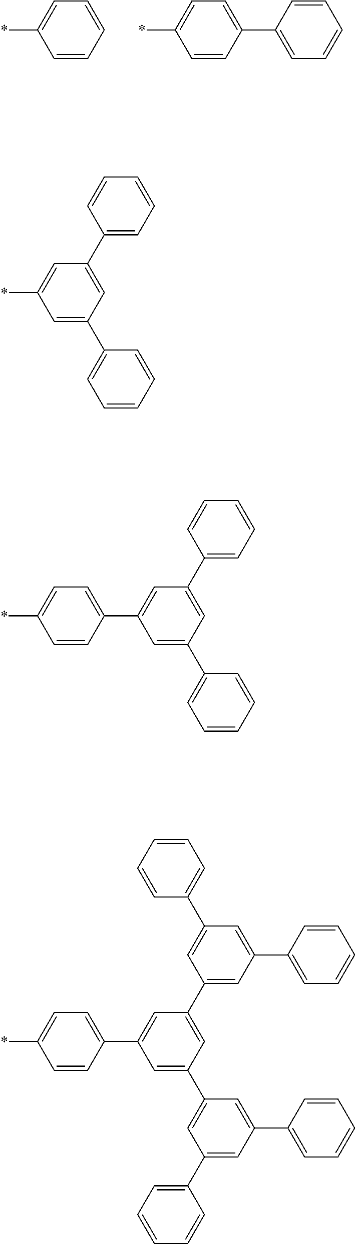

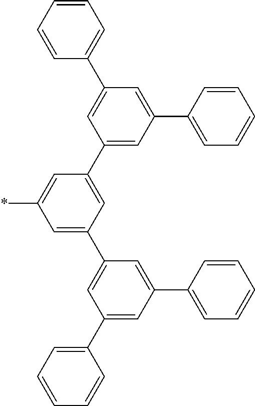 [SMILES: *c1cc(-c2cc(-c3ccccc3)cc(-c3ccccc3)c2)cc(-c2cc(-c3ccccc3)cc(-c3ccccc3)c2)c1]

wherein * represents a point of attachment of the substituent to the metal complex.

Optionally, R² of compounds of formula (I) is selected from substituents R³ as described above, optionally C₁₋₄₀ hydrocarbyl.

Exemplary compounds of formula (Ia) are illustrated below:

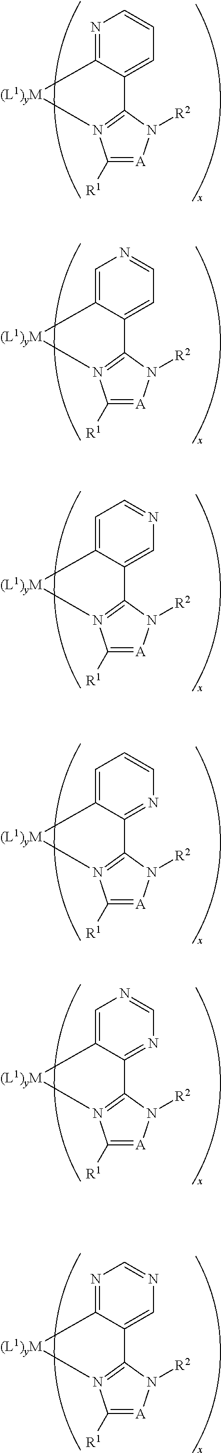

M of compounds of formula (I) may be selected from heavy metal transition metal complexes, optionally ruthenium, rhodium, palladium, rhenium, osmium, iridium, platinum and gold. Iridium is particularly preferred.

In one optional arrangement, x is 3 and y is 0.

In another optional arrangement, y is a positive integer, optionally 1 or 2, and each L¹ is independently a monodentate or polydentate ligand. Exemplary ligands L¹ include tetrakis-(pyrazol-1-yl)borate, 2-carboxypyridyl and diketonates, for example acetylacetonate.

Exemplary compounds of formula (I) are illustrated below:

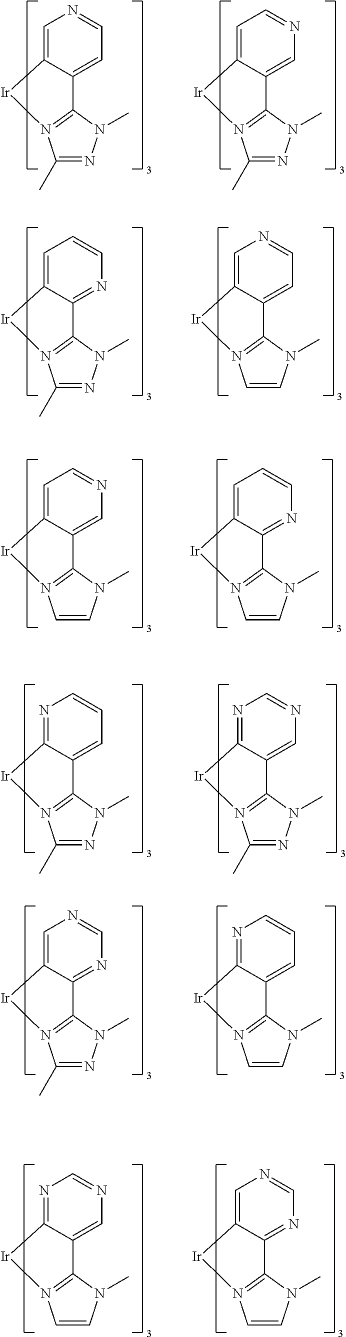

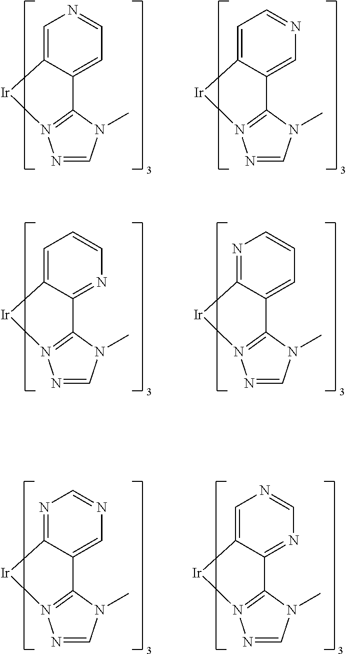

### Host Material

The host material may be a small molecule or polymeric light-emitting material.

The triplet energy level of the host material is preferably no more than 0.1 eV below that of the compound of formula (I), and is more preferably about the same or higher than that of the light-emitting material in order to avoid quenching of phosphorescence from the compound of formula (I). Triplet energy levels may be measured from the energy onset of the phosphorescence spectrum measured by low temperature phosphorescence spectroscopy (Y. V. Romaovskii et al, Physical Review Letters, 2000, 85 (5), p 1027, A. van Dijken et al, Journal of the American Chemical Society, 2004, 126, p 7718).

The compound of formula (I) may be mixed with the host material or may be covalently bound to the host material. In the case where the host material is a polymer, the compound of formula (I) may be provided as a main chain repeat unit, a side group pendant from a repeat unit in the main chain of the polymer or an end group of the polymer. It will therefore be understood that a “composition” of a host material and phosphorescent material as described herein includes a mixture of separate host and phosphorescent materials and a host material having a phosphorescent material bound thereto.

In the case where the compound of formula (I) is provided as a side group, the compound may be directly bound to a main chain of the polymer or spaced apart from the main chain by a spacer group. Exemplary spacer groups include C₁₋₂₀ alkyl groups, aryl-C₁₋₂₀ alkyl groups and C₁₋₂₀ alkoxy groups.

If the compound of formula (I) is bound to a polymer comprising conjugated repeat units then it may be bound to the polymer such that there is no conjugation between the conjugated repeat units and the compound of formula (I), or such that the extent of conjugation between the conjugated repeat units and the compound of formula (I) is limited.

Exemplary hosts include triazine hosts. An exemplary small molecule triazine host has formula (II):

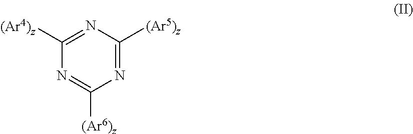

wherein Ar⁴, Ar⁵ and Ar⁶ in each occurrence are independently selected from aryl or heteroaryl, Ar⁴, Ar⁵ and Ar⁶ independently in each occurrence may be unsubstituted or substituted with one or more substituents; and z in each occurrence is 1, 2 or 3.

Optionally, Ar⁴, Ar⁵ and Ar⁶ are each phenyl. Each phenyl group may be unsubstituted or substituted with one or more substituents.

Exemplary substituents of Ar⁴, Ar⁵ and Ar⁶, if present, include C₁₋₂₀ alkyl wherein one or more non-adjacent C atoms may be replaced with O, S, NR⁵, CO or COO wherein R⁵ is H or a substituent, optionally C₁₋₂₀ hydrocarbyl, and one or more H atoms may be replaced with F.

Exemplary host compounds of formula (II) include the following:

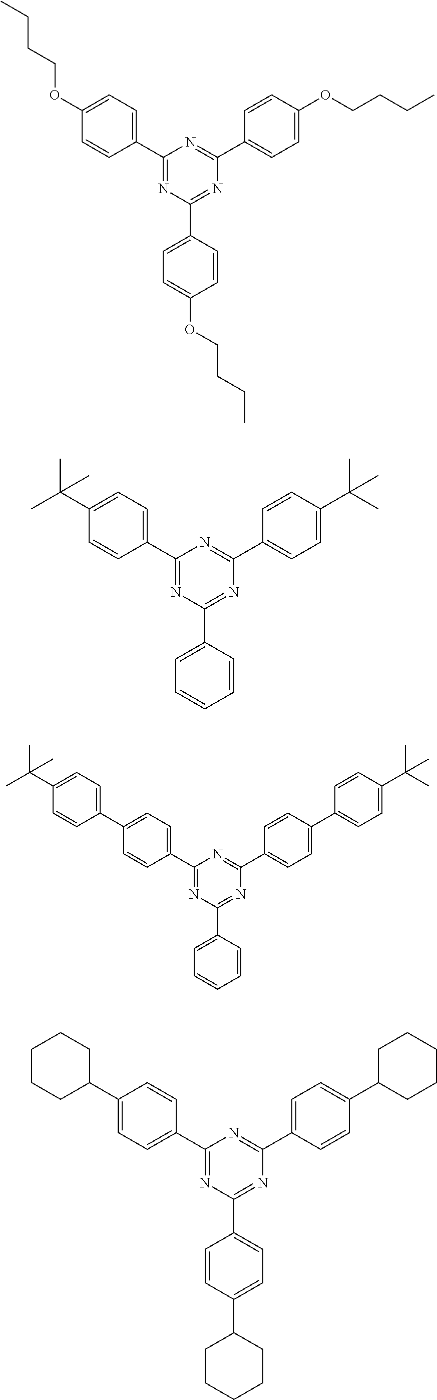

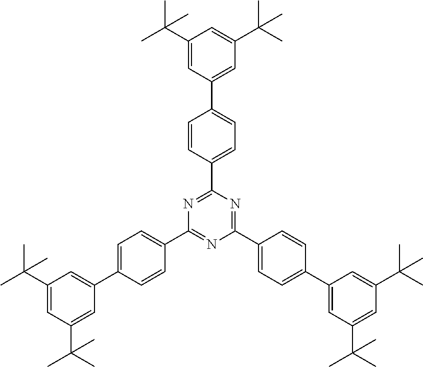 [SMILES: CC(C)(C)c1cc(-c2ccc(-c3nc(-c4ccc(-c5cc(C(C)(C)C)cc(C(C)(C)C)c5)cc4)nc(-c4ccc(-c5cc(C(C)(C)C)cc(C(C)(C)C)c5)cc4)n3)cc2)cc(C(C)(C)C)c1]

The host may be a polymer comprising triazine repeat units. Optionally, the polymer comprises repeat units of formula (IV):

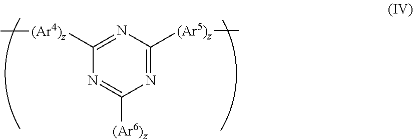

wherein Ar⁴, Ar⁵ and Ar⁶ and z are as described with reference to formula (III) above, and may each independently be substituted with one or more substituents described with reference to formula (III).

Host polymers of compositions of the invention are suitably amorphous polymers.

A preferred repeat unit of formula (IV) is 2,4,6-triphenyl-1,3,5-triazine wherein the phenyl groups are each independently unsubstituted or substituted. The repeat unit of formula (IV) may have formula (IVa), wherein each phenyl may independently be unsubstituted, or substituted with one or more substituents, optionally one or more C₁₋₂₀ alkyl groups:

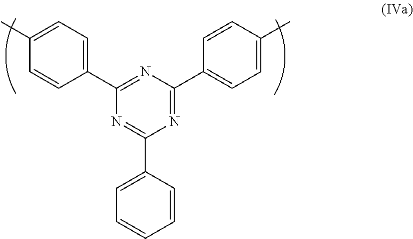

The triazine repeat units may be provided as distinct repeat units formed by polymerising a corresponding monomer wherein Ar⁴ and Ar⁵ are substituted with a leaving group capable of reacting to form a repeat unit of formula (IV). Alternatively, the triazine units may form part of a larger repeat unit, for example a repeat unit of formula (V):

(Ar³)_{q}-Sp-Tz-Sp-(Ar³)_{q} (V)

wherein Tz represents a group comprising triazine, for example a group of formula (IV); each Ar³ independently represents an unsubstituted or substituted aryl or heteroaryl; q is at least 1, optionally 1, 2 or 3; and each Sp independently represents a spacer group forming a break in conjugation between Ar³ and Tz.

Sp is preferably a branched, linear or cyclic C₁₋₂₀ alkyl group wherein one or more non-adjacent C atoms may be replaced with O, S, C═OO, C═O or —SiR⁵₂— wherein R⁵ in each occurrence independently represents a substituent, optionally a C₁₋₂₀ hydrocarbyl.

Ar³ is preferably an unsubstituted or substituted aryl, optionally an unsubstituted or substituted phenyl or fluorene. Optional substituents for Ar³ may be selected from R³ as described above, and are preferably selected from one or more C₁₋₂₀ alkyl substituents.

Each q is preferably 1.

A polymer comprising triazine-containing repeat units may be a copolymer containing one or more further repeat units. Exemplary further repeat units include arylene repeat units, such as disclosed in for example, Adv. Mater. 2000 12(23) 1737-1750. Exemplary arylene co-repeat units include 1,2-, 1,3- and 1,4-phenylene repeat units as disclosed in J. Appl. Phys. 1996, 79, 934; 2,7-fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

One exemplary class of arylene repeat units is optionally substituted fluorene repeat units, such as repeat units of formula (VI):

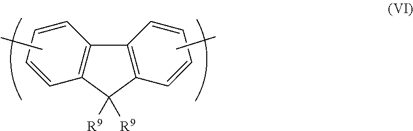

wherein R⁹ in each occurrence is the same or different and is H or a substituent, and wherein the two groups R⁹ may be linked to form a ring.

Each R⁹ is preferably a substituent, and each R⁹ may independently be selected from the group consisting of:
optionally substituted alkyl, optionally C₁₋₂₀ alkyl, wherein one or more non-adjacent C atoms may be replaced with optionally substituted aryl or heteroaryl, O, S, substituted N, C═O or —COO—;
optionally substituted aryl or heteroaryl;
a linear or branched chain of aryl or heteroaryl, each of which groups may independently be substituted, for example a group of formula —(Ar⁷), wherein Ar⁷ in each occurrence is an optionally substituted aryl or heteroaryl group, optionally phenyl, and r is at least 2, optionally 2 or 3; and
a crosslinkable-group, for example a group comprising a double bond such and a vinyl or acrylate group, or a benzocyclobutane group.

In the case where R⁹ comprises aryl or heteroaryl ring system, or a linear or branched chain of aryl or heteroaryl ring systems, the or each aryl or heteroaryl ring system may be substituted with one or more substituents R⁷ selected from the group consisting of:
alkyl, for example C₁₋₂₀ alkyl, wherein one or more non-adjacent C atoms may be replaced with O, S, substituted N, C═O and —COO— and one or more H atoms of the alkyl group may be replaced with F or aryl or heteroaryl optionally substituted with one or more groups R¹⁴,
aryl or heteroaryl optionally substituted with one or more groups R¹⁴,
NR¹⁵₂, OR¹⁵, SR¹⁵, and
fluorine, nitro and cyano;
   wherein each R¹⁴ is independently alkyl, for example C₁₋₂₀ alkyl, in which one or more non-adjacent C atoms may be replaced with O, S, substituted N, C═O and —COO— and one or more H atoms of the alkyl group may be replaced with F, and each R¹⁵ is independently selected from the group consisting of alkyl and aryl or heteroaryl optionally substituted with one or more alkyl groups.

Optional substituents for one or more of the aromatic carbon atoms of the fluorene unit are preferably selected from the group consisting of alkyl, for example C₁₋₂₀ alkyl, wherein one or more non-adjacent C atoms may be replaced with O, S, NH or substituted N, C═O and —COO—, optionally substituted aryl, optionally substituted heteroaryl, alkoxy, alkylthio, fluorine, cyano and arylalkyl. Particularly preferred substituents include C₁₋₆₀ hydrocarbyl, for example C₁₋₂₀ alkyl and substituted or unsubstituted aryl, for example phenyl. Optional substituents for the aryl include one or more C₁₋₂₀ alkyl groups.

Where present, substituted N may independently in each occurrence be NR⁶ wherein R⁶ is alkyl, optionally C₁₋₂₀ alkyl, or optionally substituted aryl or heteroaryl.

Preferably, each R⁹ is selected from the group consisting of C₁₋₄₀ hydrocarbyl, for example C₁₋₂₀ alkyl and optionally substituted phenyl. Optional substituents for phenyl include one or more C₁₋₂₀ alkyl groups.

If the compound of formula (I) is provided as a side-chain of the polymer then at least one R⁹ may comprise a compound of formula (I) that is either bound directly to the 9-position of a fluorene unit of formula (VI) or spaced apart from the 9-position by a spacer group.

The repeat unit of formula (VI) may be a 2,7-linked repeat unit of formula (VIa):

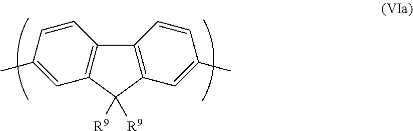

In one optional arrangement, the repeat unit of formula (VIa) is not substituted in a position adjacent to the 2- or 7-position. Linkage through the 2- and 7-positions and absence of substituents adjacent to these linking positions may provide a repeat unit that is capable of providing a relatively high degree of conjugation across the repeat unit.

In another optional arrangement, the repeat unit of formula (VIa) is substituted in a position adjacent to the 2- or 7-position. Substituents adjacent to these linking positions, for example in the 3- and/or 6-positions, may create a twist in the polymer backbone and provide a repeat unit with a relatively low degree of conjugation across the repeat unit.

The repeat unit of formula (VI) may be an optionally substituted 3,6-linked repeat unit of formula (VIb)

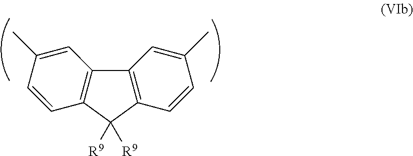

The extent of conjugation across a repeat unit of formula (VIb) may be relatively low as compared to a repeat unit of formula (VIa).

Another exemplary arylene repeat unit has formula (VII):

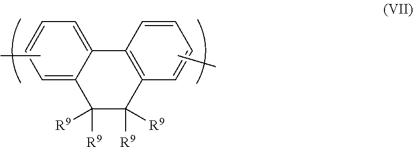

wherein R⁹ is as described with reference to formula (VI) above. Any of the R⁹ groups may be linked to any other of the R⁹ groups to form a substituted or unsubstituted ring.

Optional substituents for one or more of the aromatic carbon atoms of the repeat unit of formula (VII) are as described for the repeat unit of formula (VI).

Repeat units of formula (VII) may have formula (VIIa) or (VIIb):

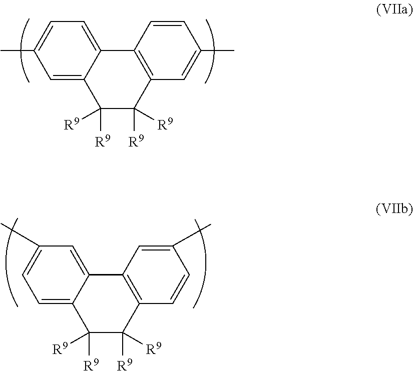

Another exemplary class of arylene repeat units is phenylene repeat units, such as phenylene repeat units of formula (VI):

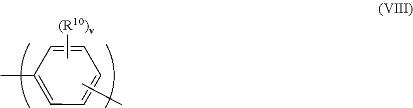

wherein v is 0, 1, 2, 3 or 4, optionally 1 or 2, and R¹⁰ independently in each occurrence is a substituent, optionally a substituent R⁹ as described above with reference to formula (VI), for example C₁₋₂₀ alkyl, and phenyl that is unsubstituted or substituted with one or more C₁₋₂₀ alkyl groups.

The repeat unit of formula (VIII) may be 1,4-linked, 1,2-linked or 1,3-linked.

If the repeat unit of formula (VIII) is 1,4-linked and if v is 0 then the extent of conjugation of repeat unit of formula (VIII) to one or both adjacent repeat units may be relatively high.

If v is at least 1, and/or the repeat unit is 1,2- or 1,3 linked, then the extent of conjugation of repeat unit of formula (VIII) to one or both adjacent repeat units may be relatively low. In one preferred arrangement, the repeat unit of formula (VIII) is 1,3-linked and v is 0, 1, 2 or 3. In another preferred arrangement, the repeat unit of formula (VIII) has formula (VIIIa):

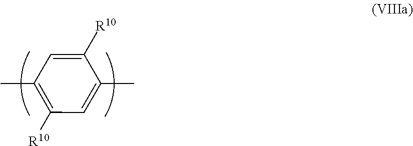

The compound of formula (I) may be mixed with the host material or may be bound to the host material. In the case where the host material is a polymer, the metal complex may be provided as a main chain repeat unit, a side group pendant from a repeat unit in the main chain of the polymer or an end group of the polymer. It will therefore be understood that a “composition” of a host material and phosphorescent material as described herein includes a mixture of separate host and phosphorescent materials and a host material having a phosphorescent material bound thereto.

The molar percentage of charge transporting repeat units in the polymer, for example repeat units of formula (II), may be in the range of up to 75 mol %, optionally in the range of up to 50 mol % of the total number of repeat units of the polymer.

In the case where the compound of formula (I) is bound to the host material then at least 0.5 mol % of repeat units of the polymer may comprise a compound of formula (I), optionally 1-50 mol %.

In the case where the compound of formula (I) is mixed with the host material, the compound of formula (I) may be provided in an amount in the range of 1 to 50 weight %, preferably 5 to 45 wt %, of the host: compound of formula (I) composition.

### Polymer Synthesis

Preferred methods for preparation of conjugated polymers, such as polymers comprising one or more of repeat units of formulae (IV), (V), (VI), (VII) or (VIII), as described above, comprise a “metal insertion” wherein the metal atom of a metal complex catalyst is inserted between an aryl or heteroaryl group and a leaving group of a monomer. Exemplary metal insertion methods are Suzuki polymerisation as described in, for example, WO 00/53656 and Yamamoto polymerisation as described in, for example, T. Yamamoto, “Electrically Conducting And Thermally Stable pi-Conjugated Poly(arylene)s Prepared by Organometallic Processes”, Progress in Polymer Science 1993, 17, 1153-1205. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units illustrated throughout this application may be derived from a monomer carrying suitable leaving groups. Likewise, an end group or side group may be bound to the polymer by reaction of a suitable leaving group.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular copolymers may be prepared when both reactive groups of a first monomer are boron and both reactive groups of a second monomer are halogen.

As alternatives to halides, other leaving groups capable of participating in metal insertion include sulfonic acids and sulfonic acid esters such as tosylate, mesylate and triflate.

### White OLEDs

An OLED containing a composition of the invention may emit white light.

The emitted white light may have CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-4500K.

White light may be formed of blue emission from a compound of formula (I), and one or more fluorescent or phosphorescent materials emitting at longer wavelengths that, together with emission of the compound of formula (I), provide white light.

A white-emitting OLED may have a single light-emitting layer emitting white light, or may contain two or more light-emitting layers wherein the light emitted from the two or more layers combine to provide white light.

### Charge Transporting and Charge Blocking Layers

A hole transporting layer may be provided between the anode and the light-emitting layer or layers. Likewise, an electron transporting layer may be provided between the cathode and the light-emitting layer or layers.

Similarly, an electron blocking layer may be provided between the anode and the light-emitting layer and a hole blocking layer may be provided between the cathode and the light-emitting layer. Transporting and blocking layers may be used in combination. Depending on its HOMO and LUMO levels, a single layer may both transport one of holes and electrons and block the other of holes and electrons.

A charge-transporting layer or charge-blocking layer may be crosslinked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group.

If present, a hole transporting layer located between the anode and the light-emitting layers preferably has a HOMO level of less than or equal to 5.5 eV, more preferably around 4.8-5.5 eV as measured by cyclic voltammetry. The HOMO level of the hole transport layer may be selected so as to be within 0.2 eV, optionally within 0.1 eV, of an adjacent layer (such as a light-emitting layer) in order to provide a small barrier to hole transport between these layers.

If present, an electron transporting layer located between the light-emitting layers and cathode preferably has a LUMO level of around 2.5-3.5 eV as measured by square wave cyclic voltammetry. For example, a layer of a silicon monoxide or silicon dioxide or other thin dielectric layer having thickness in the range of 0.2-2 nm may be provided between the light-emitting layer nearest the cathode and the cathode. HOMO and LUMO levels may be measured using cyclic voltammetry.

A hole transporting layer may contain a hole-transporting (hetero)arylamine, such as a homopolymer or copolymer comprising hole transporting amine repeat units.

If present, a charge-transporting layer adjacent to a light-emitting layer containing a compound of formula (I) preferably contains a charge-transporting material having a T₁ excited state energy level that is no more than 0.1 eV lower than, preferably the same as or higher than, the T₁ excited state energy level of the compound of formula (I) in order to avoid quenching of triplet excitons migrating from the light-emitting layer into the charge-transporting layer.

### Hole Injection Layer

A conductive hole injection layer, which may be formed from a conductive organic or inorganic material, may be provided between the anode and the light-emitting layer or layers of an OLED to improve hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx, MoOx and RuOx as disclosed in Journal of Physics D: Applied Physics (1996), 29(11), 2750-2753.

### Cathode

The cathode is selected from materials that have a workfunction allowing injection of electrons into the light-emitting layer. Other factors influence the selection of the cathode such as the possibility of adverse interactions between the cathode and the light-emitting material. The cathode may consist of a single material such as a layer of aluminium. Alternatively, it may comprise a plurality of metals, for example a bilayer of a low workfunction material and a high workfunction material such as calcium and aluminium as disclosed in WO 98/10621. The cathode may contain a layer of elemental barium as disclosed in WO 98/57381, Appl. Phys. Lett. 2002, 81(4), 634 and WO 02/84759. The cathode may contain a thin layer (e.g. 1-5 nm layer) of metal compound between the light-emitting layer(s) of the OLED and one or more conductive cathode layers, for example one or more metal layers, to assist electron injection. Metal compounds include, in particular, an oxide or fluoride of an alkali or alkali earth metal, for example lithium fluoride as disclosed in WO 00/48258; barium fluoride as disclosed in Appl. Phys. Lett. 2001, 79(5), 2001; and barium oxide. A metal compound layer may alter the effective work function of the cathode as compared to a cathode in which the metal compound layer is absent.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Organic optoelectronic devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

The device may be encapsulated with an encapsulant (not shown) to preventingress of moisture and oxygen. Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### Formulation Processing

A composition of the invention be dispersed or dissolved in a solvent or mixture of two or more solvents to form a formulation that may be used to form a layer containing the compound by depositing the formulation and evaporating the solvent or solvents. The formulation may contain one or more further materials in addition to the composition. All of the components of the composition may be dissolved in the solvent or solvent mixture, in which case the formulation is a solution, or one or more components of the composition may be dispersed in the solvent or solvent mixture. Exemplary solvents for use alone or in a solvent mixture include aromatic compounds, preferably benzene, that may be unsubstituted or substituted with one or more substituents selected from C₁₋₁₀ alkyl, C₁₋₁₀ alkoxy and halogens preferably chlorine, for example toluene, xylene or anisole.

Techniques for forming layers from a formulation include printing and coating techniques such spin-coating, dip-coating, flexographic printing, gravure printing, screen printing and inkjet printing.

Multiple organic layers of an OLED may be formed by deposition of formulations containing the active materials for each layer.

During OLED formation, a layer of the device may be crosslinked to prevent it from partially or completely dissolving in the solvent or solvents used to deposit an overlying layer. Layers that may be crosslinked include a hole-transporting layer prior to formation by solution processing of an overlying light-emitting layer, or crosslinking of one light-emitting layer prior to formation by solution processing of another, overlying light-emitting layer.

Suitable crosslinkable groups include groups comprising a reactive double bond such and a vinyl or acrylate group, or a benzocyclobutane group. Where a layer to be crosslinked contains a polymer, the crosslinkable groups may be provided as substituents of repeat units of the polymer.

Coating methods such as spin-coating are particularly suitable for devices wherein patterning of the light-emitting layer is unnecessary—for example for lighting applications or simple monochrome segmented displays.

Printing methods such as inkjet printing are particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

The invention will now be described by means of example only by reference to the following examples.

### EXAMPLES

### Synthesis of Comparative Emitter 1

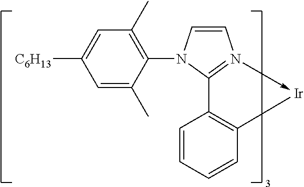

### Synthesis of Ligand 1

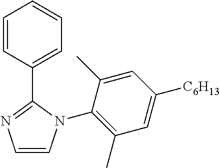

### Reaction Scheme

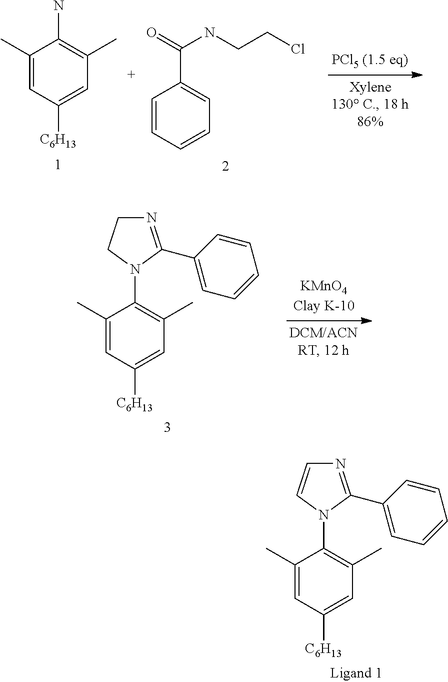

### Stage 1

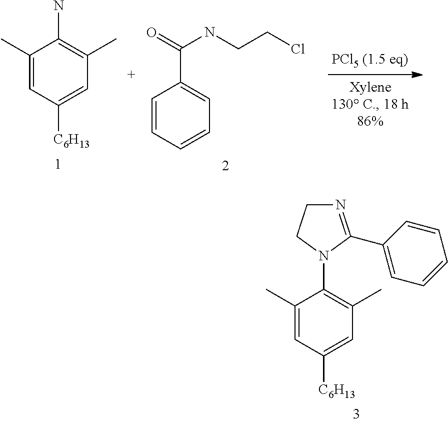

Phosphorus pentachloride (270 g, 1.3 mol) was added portionwise to a stirred solution of N-(2-chloroethyl)benzamide (160 g, 0.87 mol). After addition the mixture was heated to 130° C. and stirred for 2 h. After cooling to r.t. 4-hexyl-2,6-dimethylaniline (196 g, 0.95 mol) was added over 0.5 h. After addition the mixture was again heated to 130° C. for 18 h. The mixture was cooled and filtered through a plug of was dissolved in DCM (4 L) and washed with an aqueous solution of NaHCO₃ (2×1 L). The organic layer was washed with water, dried with sodium sulphate, filtered and concentrated. The residue was purified by column chromatography on silica eluting with DCM:MeOH (4:1 v/v) to obtain the stage 1 material (250 g, 86%).

1H NMR (referenced to CDCl₃) 7.44-7.54 (3H, m), 7.29 (2H, m), 6.85 (2H, s), 4.10-4.30 (4H, m), 2.46 (2H, t), 2.11 (6H, s), 1.48-1.52 (2H, m), 1.20-1.24 (6H, m), 0.79 (3H, t)

### Stage 2

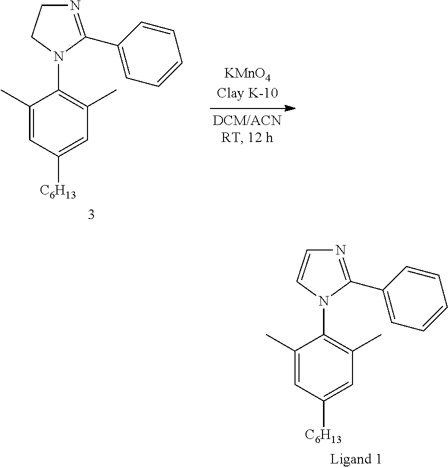

Stage 1 material (250 g, 0.75 mol) was suspended in a mixture of 4:1 acetonitrile:DCM (3 L). KMnO4 (228 g, 1.5 mol) and Montorillonite K-10 clay (456 g) were ground together and then added in portions to the reaction mixture over 20 mins which produced an exotherm. The reaction mixture was stirred for 12 hours before ethanol (300 mL) was added and stirred for a further hour. The mixture was filtered through a celite plug and eluted with ethyl acetate. The filtrate was concentrated and the obtained residue was purified by colun chromatography on silica eluting with 6-8% etyl acetate in hexanes (v/v) to give Ligand 1 as a viscous oil (78 g, 31%)

¹H NMR (referenced to CDCl₃) 7.39-7.42 (2H, m), 7.31 (1H, d), 7.20-7.24 (3H, m), 6.95 (2H, s), 6.91 (1H, d), 2.59 (2H, t), 1.93 (6H, s), 1.60-1.66 (2H, m), 1.33-1.39 (6H, m), 0.91 (3H, t)

### Comparative Emitter 1

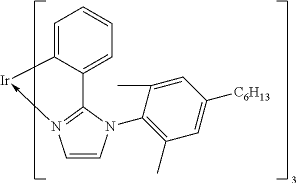

### Stage 3

Ligand 1 (10.85 g, 32.6 mmol) and iridium(III) chloride hydrate (5 g, 14.2 mmol) were suspended in 2-ethoxyethanol (200 mL) and water (65 mL). The mixture was degassed with N₂ for 1.5 h before the mixture was heated with stirring to 125° C. for 14 h. After cooling 200 mL of water was added to the stirred suspension to fully precipitate the product which was filtered and washed with water on the filter. The solid was dissolved in DCM, washed with water (2×50 mL), dried with magnesium sulfate, filtered and concentrated to ˜50 mL. 150 mL hexanes was added before the remaining DCM was removed with compressed air to precipitate stage 3 as a golden powder which was isolated by filtration and used without further purification (11.33 g).

### Stage 4

The Stage 3 material (6.5 g, 3.65 mmol), acetylacetone (0.93 mL, 9.12 mmol) and sodium carbonate (3.85 g, 36.5 mmol) were suspended in 2-ethoxyethanol (40 mL) and degassed with N₂ for 0.5 h. The mixture was then heated with stirring to 105° C. with protection from light for 20 h. After cooling the precipitate was filtered and washed with 2×200 mL water on the filter. The wet solid was added to 500 mL of water and triturated for 20 mins before being filtered. The solid was oven-dried and then precipitated from DCM/hexane and filtered to give the stage 4 material as a yellow powder which was used without further purification (6.67 g, 96%).

### Comparative Emitter 1

A round-bottom flask was charged with stage 4 material (5 g, 5.24 mmol) and ligand 1 and the setup was purged with N₂ for 1 h. The solids were stirred together at 250° C. in a melt for 48 h with protection from light. After cooling to r.t. the dark solid was dissolved in DCM and purified on a Biotage Isolera One flash column system on silica eluting with 0-10% ethyl acetate in hexanes (v/v). The product-containing fractions were combined and concentrated and the residue was re-precipitated from DCM/hexanes and filtered to obtain the product as a yellow solid (4.7 g, 76%). HPLC indicated 98% purity.

¹H NMR (referenced to DMSO-d6) 7.21 (3H, s), 7.16 (6H, d), 6.72 (3H, d), 6.64 (3H, s), 6.49 (3H, t), 6.33 (3H, t), 6.05 (3H, d), 2.65 (6H, t), 2.01 (9H, s), 1.82 (9H, s), 1.65 (6H, m), 1.33 (18H, m), 0.89 (9H, t).

### Synthesis of Emitter Example 1

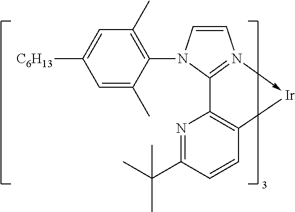

### Synthesis of Ligand 2

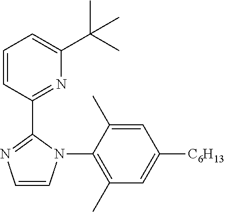

### Stage 1

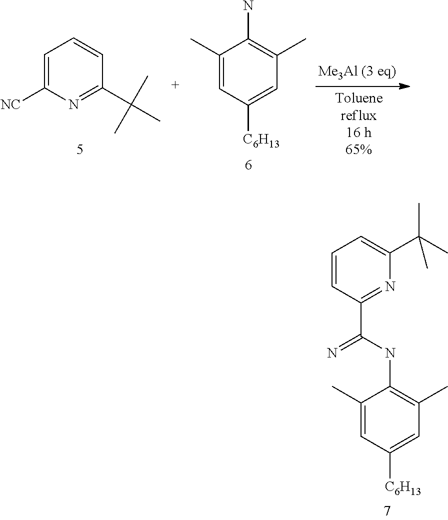

2,6-Dimethyl-4-hexylaniline (130 g, 0.81 mol) in toluene (1.1 L) was cooled to 0° C. in an ice bath. A 2 M solution of trimethylaluminium (1015 mL) was added dropwise and the mixture was stirred for 3 h at r.t before a solution of 6-tert-butylpyridine-2-carbonitrile (133 g, 0.65 mol) in toluene (200 mL) was added and the mixture was refluxed for 16 h. The cooled reaction mixture was carefully added to ice water (1.5 L) and the resulting emulsion was filtered. The toluene layer was separated and the aqueous layer was extracted with ethyl acetate (2×500 mL). The combined organic layers were washed with brine, dried with sodium sulphite, filtered and concentrated to yield the crude product which was purified by column chromatography on silica eluting with 5% ethyl acetate in petroleum ether (v/v) to isolate stage 1 as a yellow oil (110 g, 65%).

1H NMR (referenced to CDCl₃): 8.30 (1H, br s), 7.78-7.82 (1H, m), 7.47-7.49 (1H, m), 6.91 (2H, s), 6.79 (1H, s), 3.48 (1H, br s), 2.45-2.57 (2H, m), 2.19 (3H, s), 2.15 (3H, s), 1.53-1.64 (2H, m), 1.43 (9H, s), 1.33-1.40 (6H, m), 0.86-0.93 (3H, m).

### Stage 2

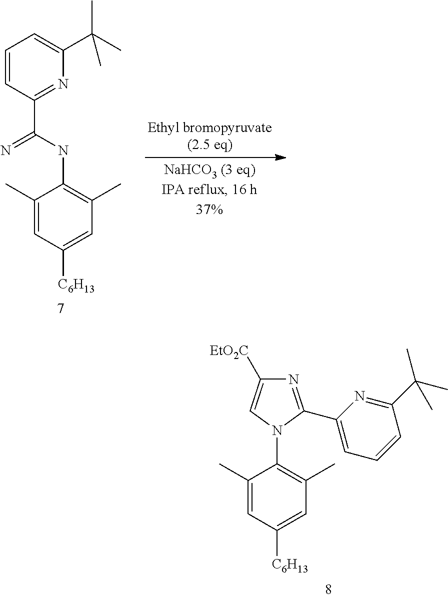

Stage 1 material (110 g, 0.3 mol) ethyl bromopyruvate (147 g, 0.75 mol) and NaHCO₃ (76 g, 0.9 mol) were taken in IPA (2 L) and refluxed for 16 h. After cooling water was added and the organics were extracted with ethyl acetate (2×500 mL). The combined organic extracts were washed with brine, dried with sodium sulphate, filtered and concentrated to yield the crude product which was purified by colun chromatography on silica eluting with 2-5% ethyl acetate in petroleum ether (v/v). The product was isolated as a red solid (50 g, 37%). HPLC showed >98% purity.

¹H NMR (referenced to CDCl₃) 8.18 (1H, d), 7.65 (1H, t), 7.57 (1H, d), 7.17 (1H, d), 6.92 (2H, s), 4.44 (2H, q), 2.55 (2H, t), 1.93 (6H, s), 1.57-1.60 (2H, m), 1.43 (3H, t), 1.26-1.34 (6H, m), 0.91 (3H, t), 0.89 (9H, s).

### Stage 3

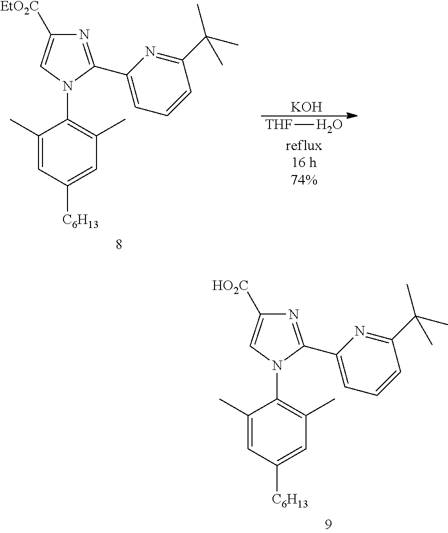

Stage 2 material (60 g, 0.13 mol) and KOH (19 g, 0.33 mol) were taken in 2:1 THF:water (v/v, 1 L) and refluxed for 16 h. After cooling the THF was removed and the mixture was acidified with conc. HCl to pH-2-3 and the organics were extracted with DCM (2×500 mL). The combined organic extracts were washed with brine, dried with sodium sulphate, filtered and concentrated to yield the crude product which was triturated with petroleum ether and dried under vacuum to give stage 3 material as a white solid (41 g, 74%). HPLC indicated >99% purity.

¹H NMR (referenced to CDCl₃) 12.50 (1H, br s), (1H, d), 7.90 (1H, m), 7.75-7.81 (2H, m), 7.26 (1H, d), 6.97 (2H, s), 2.48 (2H, t), 1.83 (6H, s), 1.52-1.55 (2H, m), 1.20-1.30 (6H, m), 0.86 (3H, t), 0.85 (9H, s).

### Ligand 2

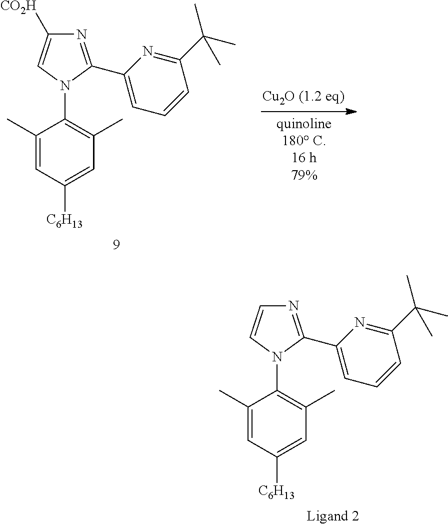

Stage 3 material (20 g, 46 mmol) and Cu₂O (9.9 g, 69 mmol) were taken in quinoline (200 mL) and heated to 180° C. for 16 h. The qinoline was removed by distillation and the residue was taken up in ethyl acetate and filtered through celite. The filtrate was washed with 10% citric acid solution (200 mL) followed by brine and then dried over sodium sulphite, filtered and concentrated. The crude residue was purified by column chromatography on silica eluting was 3-5% ethyl acetate in petroleum ether (v/v) to give Ligand 2 (14 g, 79%). HPLC indicated >99% purity.

¹H NMR (referenced to CDCl₃): 8.01 (1H, m), 7.63 (1H, t), 7.32 (1H, m), 7.11-7.13 (1H, m), 6.93 (2H, s), 6.90 (1H, m), 2.56 (2H, t), 1.93 (6H, s), 1.58-1.64 (2H, m), 1.33-1.42 (6H, m), 0.93 (3H, t), 0.91 (9H, s).

### Emitter Example 1

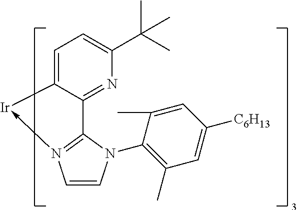

### Stage 1

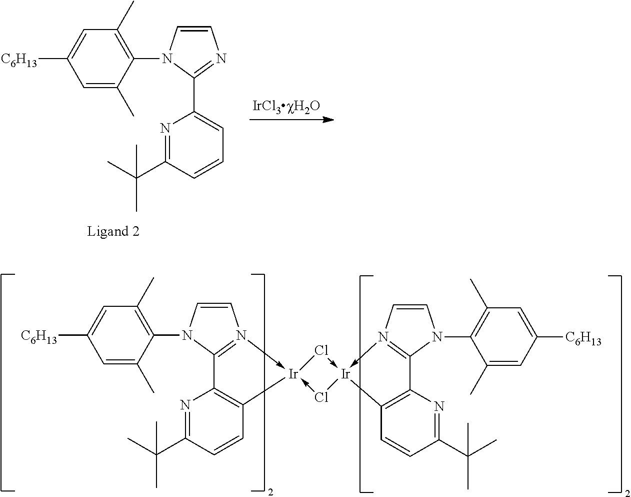

Ligand 3 (10 g, 25.7 mmol) and iridium(III) chloride hydrate (4.1 g, 11.7 mmol) were taken in 2-ethoxyethanol (150 mL) and water (50 mL) and degassed for 1 h before being heated to 125° C. for 14 h. After cooling ˜50 mL water was added to fully precipitate the product which was filtered and washed with water. The solid was dissolved in diethyl ether and concentrated to give stage 1 as a foamy red solid which was used without further purification (11.7 g).

### Stage 2

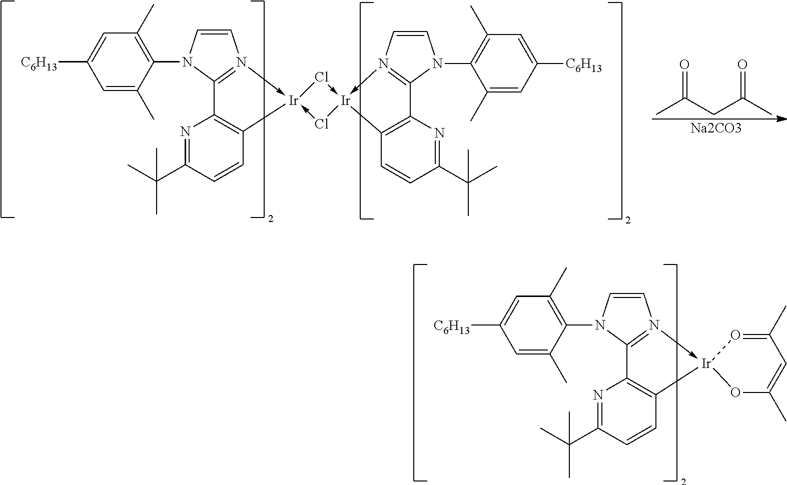

Crude stage 1 material (11.7 g) acetylacetone (1.5 g, 15 mmol) and sodium carbonate (6.15 g, 58 mmol) were taken in 2-ethoxyethanol (150 mL) and degassed for 1 h. The mixture was heated to 105° C. for 24 h. After cooling 100 mL water was added. The solid obtained was filtered and washed with water before being dissolved in THF and added to ˜1 L water to precipitate a red solid which was filtered. The solida was purified on a Biotage Isolera One flash column system on silica eluting with 5-25% ethyl acetate in hexanes The product-containing fractions were concentrated and precipitated from DCM into methanol to give the stage 2 material which was used without further purification (4.08 g, 33%).

### Emitter Example 1

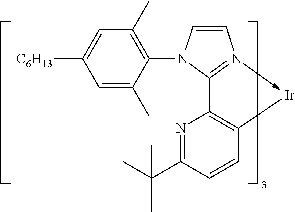

Stage 2 material (3.5 g, 3.3 mmol) and Ligand 2 (2.6 g, 6.6 mol) were heated in a melt under N₂ to 250° C. for 48 h with protection from light. After cooling the material was dissolved in toluene. The crude mixture was purified on a Biotage Isolera One flash column system on silica eluting with 0-20% ethyl acetate in hexanes. The product-containing fractions were re-precipitated from DCM/methanol and again columned on silica eluting with a mixture of ethyl acetate, DCM and hexanes and precipitated from DCM/acetonitrile to yield a yellow powder (2.9 g, 65%). HPLC indicated a purity of 98.11%.

¹H NMR (referenced to CDCl₃): 6.96 (6H, s), 6.72 (6H, br), 6.00 (6H, br), 2.58 (6H, t), 2.06 (9H, s), 1.88 (9H, s), 1.65-1.62 (6H, m), 1.43-1.37 (6H, m), 1.35-1.33 (12H, m), 0.93-0.91 (36H, m).

### Example Host Polymer 1

A host polymer containing triphenyltriazine repeat units was prepared by Suzuki polymerisation as described in WO 00/53656 of the following monomers in a 1:1 ratio:

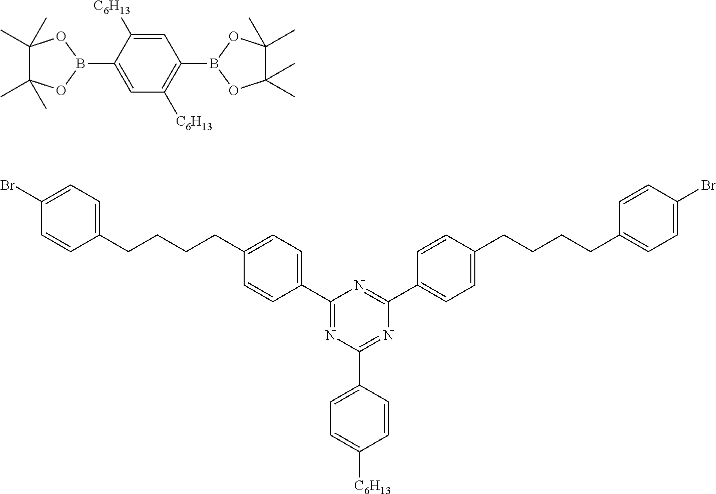

Example Host Polymer 1 has a HOMO level deeper than −6 eV and a LUMO level of −2.65 eV.

### Comparative Host Polymer 1

For the purpose of comparison, a host polymer containing triphenyltriazine repeat units was prepared by Suzuki polymerisation as described in WO 00/53656 of the following monomers in a 1:1 ratio

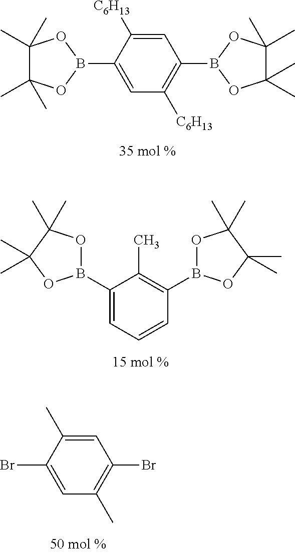

Comparative Host Polymer 1 has a HOMO level of deeper than −6 eV and a LUMO level shallower than −1.8 eV.

### Comparative Compositions

Compositions of 5 weight % of Comparative Emitter 1 dispersed in Example Host Polymer 1 and in Comparative Host Polymer 1 were prepared.

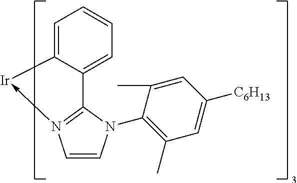

### Comparative Emitter 1

A film of the composition was cast by spin-coating and a photoluminescence spectrum of the composition was generated.

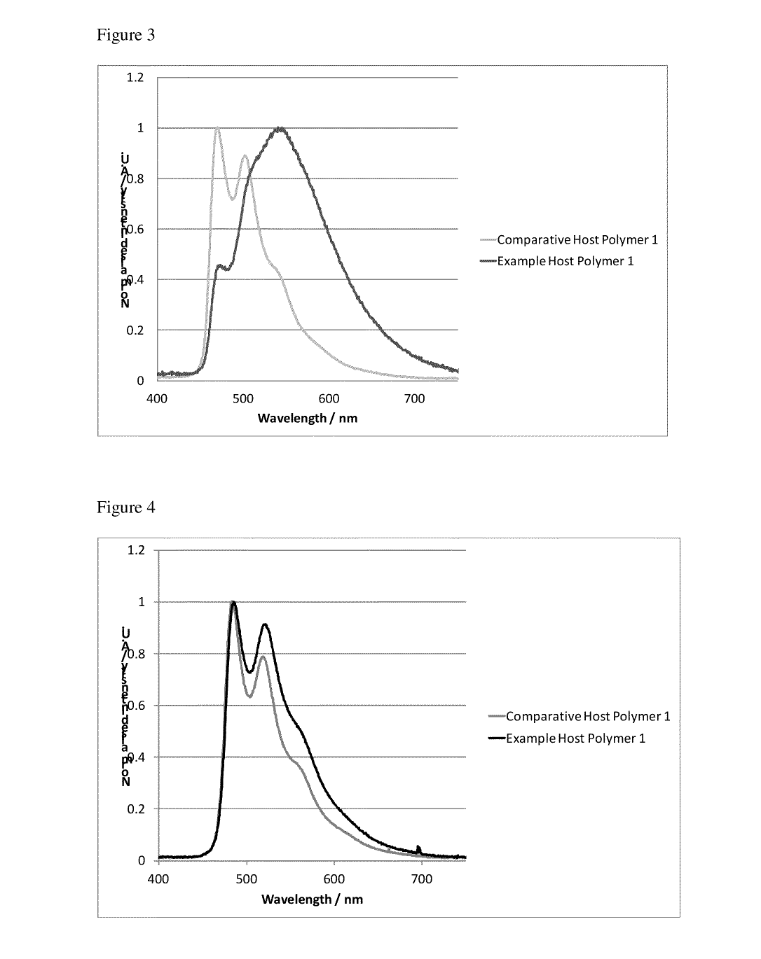

With reference to FIG. 3, Comparative Emitter 1 dispersed in Comparative Host Polymer 1 provides a sharp and well-defined spectrum showing emission from Comparative Emitter. However, the same emitter dispersed in Example Host Polymer 1 produced a broader spectrum peaking at a longer wavelength.

Without wishing to be bound by any theory, it is believed that the relatively shallow HOMO level of Comparative Emitter 1 results in formation of an exciplex between the HOMO of Comparative Emitter 1 and the LUMO of the triazine-containing Example host polymer 1.

### Example Composition

A composition of 5 weight % of Emitter Example 1 dispersed in Example Host Polymer 1 was prepared.

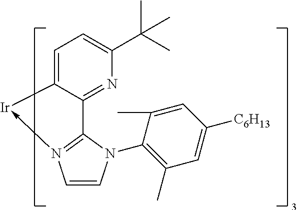

### Example Emitter 1

With reference to FIG. 4 it can be seen that exciplex emission observed in FIG. 3 is substantially or completely eliminated, and emission using Example Emitter 1 with Example Host Polymer 1 is similar to that of Example Emitter 1 dispersed in Comparative Host Polymer 1.

With reference to Table 1, Example Emitter 1 has a HOMO level that is deeper (further from vacuum level) than Comparative Emitter 1.

TABLE 1

| Emitter | HOMO (eV) | LUMO (eV) |
|---|---|---|
| Comparative Emitter 1 | −4.82 | −1.86 |
| Example Emitter 1 | −4.98 | −1.74 |

Without wishing to be bound by any theory, it is believed that the electron-deficient pyridine of Example Emitter 1 deepens the HOMO level of the emitter (i.e. moves it further from vacuum), thereby increasing the emitter HOMO-host LUMO gap and reducing the probability of exciplex formation.

Furthermore, the LUMO level of Example Emitter 1 is not deeper, and is in fact shallower, that that of Comparative Emitter 1. Consequently, Emitter Example 1 has a larger HOMO-LUMO gap than Comparative Emitter 1.

Photoluminescent quantum yield (PLQY) of compositions described herein are set out in Table 2.

TABLE 2

| Emitter | Host polymer | PLQY/% | CIE X | CIE Y |
|---|---|---|---|---|
| Comparative | Comparative Host | 63 | 0.197 | 0.389 |
| Emitter 1 | Polymer 1 | | | |
| Example | Comparative Host | 71 | 0.24 | 0.506 |
| Emitter 1 | Polymer 1 | | | |
| Comparative | Example Host | 46 | 0.359 | 0.513 |
| Emitter 1 | Polymer 1 | | | |
| Example | Example Host | 79 | 0.274 | 0.53 |
| Emitter 1 | Polymer 1 | | | |

With reference to Table 2, it can be seen that the combination of Example Emitter 1 and Example Host Polymer 1 provides the highest PLQY value.

Thus, although Comparative Host Polymer 1 does not produce exciplexes with either Example Emitter 1 or Comparative Emitter 1, it provides a lower efficiency than Example Host Polymer 1. Without wishing to be bound by any theory, it is believed that the higher efficiency achieved using Example Host Polymer 1 is due to its superior electron-transporting capabilities. Accordingly, the invention may provide high efficiency compositions without exciplex formation.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A composition comprising a compound of formula (I) and a host material: 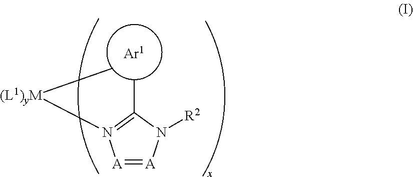
wherein:
Ar¹ is a nitrogen-containing heteroaryl group that may be unsubstituted or substituted with one or more substituents;
R² is a substituent;
A is independently in each occurrence N or CR³ wherein R³ is H or a substituent;
M is a transition metal or metal ion;
x is a positive integer of at least 1;
y is 0 or a positive integer; and
each L¹ is independently a mono- or polydentate ligand different from ligands of formula 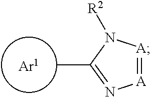
and wherein the host has a LUMO level of at least 2.0 eV from vacuum level.

2. A composition according to claim 1 wherein y=0.

3. A composition according to claim 1 or 2 wherein x=3.

4. A composition according to claim 1 wherein M is an iridium ion.

5. A composition according to claim 1 wherein Ar¹ is pyridine or pyrimidine.

6. A composition according to claim 1 wherein the compound of formula (I) has formula (Ia): 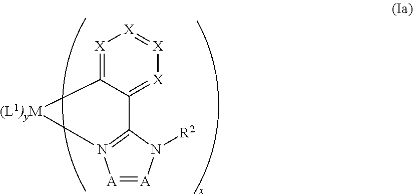
wherein X in each occurrence is N or CR³ wherein R³ in each occurrence is independently H or a substituent, with the proviso that at least one X is N.

7. A composition according to claim 1 wherein R³ is selected from the group consisting of:
alkyl wherein one or more non-adjacent C atoms of the alkyl may be replaced with optionally substituted aryl or heteroaryl, O, S, NR⁵, C═O or —COO— wherein R⁵ is H or a substituent, and one or more H atoms of the alkyl may be replaced with F;
(Ar⁹)_{w} wherein Ar⁹ is independently in each occurrence an aryl or heteroaryl group that may be unsubstituted or substituted with one or more substituents, and w is at least 1.

8. A composition according to claim 1 wherein R² is a C₁₋₄₀ hydrocarbyl group.

9. A composition according to claim 1 wherein the host comprises triazine.

10. A composition according to claim 1 wherein the host material is a host polymer.

11. A composition according to claim 10 wherein the polymer comprises repeat units of formula (II): 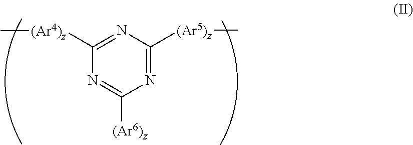
wherein Ar⁴, Ar⁵ and Ar⁶ are each independently represent an aryl or heteroaryl group that may be unsubstituted or substituted with one or more substituents; and z is a positive integer.

12. A composition according to claim 11 wherein z is 1, 2 or 3.

13. A composition according to claim 11 wherein Ar⁴, Ar⁵ and Ar⁶ in each occurrence is independently phenyl that may be unsubstituted or substituted with one or more substituents.

14. A formulation comprising a composition according to claim 1 and at least one solvent.

15. An organic light-emitting device comprising an anode, a cathode and a light-emitting layer between the anode and the cathode, the light-emitting layer comprising a composition according to claim 1.

16. A method of forming an organic light-emitting device according to claim 15, the method comprising the steps of forming the light-emitting layer over one of the anode and cathode, and forming the other of the anode and cathode over the light-emitting layer.

17. A method of forming an organic light-emitting device, comprising:
forming an anode, a cathode and a light-emitting layer between the anode and the cathode,
wherein, forming the light-emitting layer includes depositing a formulation, the formulation comprising a composition and at least one solvent, over one of the anode and the cathode and evaporating the at least one solvent,
the composition comprising, a compound of formula (I) and a host material: 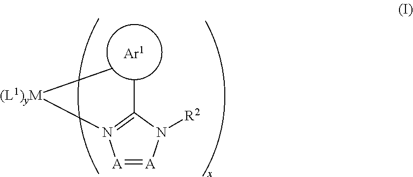
wherein:
Ar¹ is a nitrogen-containing heteroaryl group that may be unsubstituted or substituted with one or more substituents;
R² is a substituent;
A is independently in each occurrence N or CR³ wherein R³ is H or a substituent;
M is a transition metal or metal ion;
x is a positive integer of at least 1;
y is 0 or a positive integer; and
each L¹ is independently a mono- or polydentate ligand different from ligands of formula 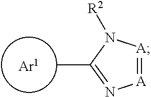
and wherein the host has a LUMO level of at least 2.0 eV from vacuum level.
